(19) United States
(12) Patent Application Publication
(10) Pub. No.: US 2007/0002733 A1
(43) Pub. Date: Jan. 4, 2007

(54) Communication apparatus and communication method

(75) Inventors: Junichiro Shitami, Kawasaki (JP); Jun Kawai, Kawasaki (JP); Osamu Shimokuni, Tokyo (JP)

Correspondence Address: KATTEN MUCHIN ROSENMAN LLP, 575 MADISON AVENUE, NEW YORK, NY, 10022-2585, US

(73) Assignee: FUJITSU LIMITED

(21) Appl. No.: 11/230,262

(22) Filed: Sep. 19, 2005

(30) Foreign Application Priority Data
Jun. 30, 2005 (JP) JP2005-192475

(51) Int. Cl. H04L 12/26; H04J 1/16; H04L 1/00; G01R 31/08

(52) U.S. Cl. 370/229; 370/252

(57) ABSTRACT

To provide a technology capable of ensuring a communication traffic on a communication route simply by providing a communication node with this technology in a network such as the Internet where communication control devices on communication routes employed for forwarding data are not all uniformly managed. A communication traffic of a first flow that contributes to a band of communication with a partner communication device is measured, a communication traffic of a second flow is calculated so that a total communication traffic of the first flow communication traffic measured and the communication traffic of the second flow that can be generated based on a result of the measurement, converges at within a predetermined range, and the communication traffic of the second flow is generated with respect to the partner communication device on the basis of a result of the calculation.

### BACKGROUND OF THE INVENTION

1. Field of the Invention

The present invention relates to a communication apparatus and a communication method.

2. Description of the Related Art

At the present, a variety of communication methods such as ATM (Asynchronous Transfer Mode) and the Internet are provided.

An ATM-based communication control device allocates, on the occasion of performing communications, bands respectively to communication routes employed by individual users. Therefore, in the case of the ATM, the communications performed by the plurality of users do not affect each other, and the individual users can perform the communications without being affected by other users.

Further, in the Internet, the communication route between the two communication nodes is ensured by using a protocol such as RSVP (Resource reSerVation Protocol). Then, the RSVP is capable of actualizing QoS (Quality of Service) control by ensuring communication resources such as bands and buffers on the ensured communication route.

Moreover, in a general packet network, [Japanese Patent Application Laid-Open No. 5-14410] is given as a technology for improving performance of a communication method of allocating the bands beforehand. The technology disclosed in [Japanese Patent Application Laid-Open No. 5-14410] is that a band usable without any restriction is ensured on the communication control device and then utilized. Hence, it is possible to restrain a delay due to a change in allocation of the bands.

In the case of the ATM, however, all the ATM-based communication control devices on the communication routes employed by the individual users are required to have a function of allocating bands matching with bands requested by the individual users. It is therefore required that the ATM be uniformly managed. Hence, the communication method such as the ATM has a difficulty of flexibly building up and administering a large-scale network including a multiplicity of common carriers and multiple networks (sub-networks).

Further, also in the protocols such as the RSVP, the communication control devices that these protocols are introduced are required to be uniformly managed. These conditions are hard to implement if all the communication control devices on the communication routes used for forwarding the data are not uniformly managed as in the Internet.

Moreover, also in the technology disclosed in [Japanese Patent Application Laid-Open No. 5-14410], the basic characteristic of requiring the band management and the band allocation in the communication control device on the communication route used for forwarding the data, is the same as in other technologies and has the same difficulty as the protocols such as the RSVP have.

The following are related arts to the present invention.
[Patent document 1] Japanese Patent Application Laid-Open Publication No. 5-14410
[Patent document 2] Japanese Patent Application Laid-Open Publication No. 2000-261435
[Patent document 3] Japanese Patent Application Laid-Open Publication No. 2000-244524
[Patent document 4] Japanese Patent Application Laid-Open Publication No. 2003-163690
[Patent document 5] Japanese Patent Application Laid-Open Publication No. 2000-151692
[Patent document 6] Japanese Patent Application Laid-Open Publication No. 8-340338
[Patent document 7] Japanese Patent Application Laid-Open Publication No. 2001-177545
[Patent document 8] Japanese Patent Application Laid-Open Publication No. 2001-177548
[Patent document 9] Japanese Patent Application Laid-Open Publication No. 2001-186150
[Patent document 10] Japanese Patent Application Laid-Open Publication No. 2001-186151
[Patent document 11] Japanese Patent Application Laid-Open Publication No. 2001-203700
[Patent document 12] Japanese Patent Application Laid-Open Publication No. 2001-203725

### SUMMARY OF THE INVENTION

The present invention is devised in view of such points. It is an object of the present invention to provide a technology capable of ensuring a communication traffic on a communication route simply by providing a communication node with this technology in a network such as the Internet where communication control apparatuses on communication routes employed for forwarding data are not all uniformly managed.

To solve the above problems, the present invention adopts the following configurations.

(1) Namely, a communication apparatus comprises measuring means measuring a communication traffic of a first flow that contributes to a band of communication with a partner communication apparatus, calculating means calculating a communication traffic of a second flow so that a total communication traffic of the first flow communication traffic measured by the measuring means and the communication traffic of the second flow that can be generated based on a result of the measurement made by the measuring means, converges at within a predetermined range, and means generating the communication traffic of the second flow with respect to the partner communication apparatus on the basis of a result of the calculation made by the calculating means.

According to this configuration, this communication apparatus is capable of converging, at within the predetermined range, the total communication traffic of the first flow communication traffic received and the communication traffic of the second flow that is generated based on the communication traffic of the first flow. Accordingly, the communication route for the communication traffic of the second flow is ensured, whereby when the communication traffic of the second flow rises, the communication traffic ensured by the communication traffic of the second flow can be used by the first flow.

(2) Further, the measuring means of this communication apparatus may include means reading a destination address of the partner communication apparatus from the communication traffic of the first flow that contributes to the communication traffic with the partner communication apparatus, judging means judging whether or not the destination address read by the reading means is coincident with a predetermined destination address, and communication traffic measuring means measuring a communication traffic to the destination address judged to be coincident by the judging means.

According to this configuration, the communication apparatus ensures the communication route with the second flow communication traffic containing a specified destination address, whereby when the first flow communication traffic containing the specified destination address rises, the communication traffic ensured by the second flow communication traffic containing the specified destination address can be used by the first flow containing the specified destination address.

(3) Moreover, this communication apparatus may further comprise differential means obtaining a size which is calculated by subtracting a size of the first flow communication traffic measured by the measuring means from a size of the first flow communication traffic measured last time by the measuring means, second calculating means calculating a communication traffic of a size which is calculated by subtracting a size of the second flow communication traffic calculated by the calculating means after being measured last time by the measuring means from a difference size of the communication traffic that is obtained by the differential means, and means controlling to generate the communication traffic of the second flow for forwarding it to the partner communication apparatus on the basis of a result of the calculation made by the second calculating means.

According to this configuration, the communication apparatus reduces a quantity of generation of the second flow communication traffic corresponding to an increase in the first flow communication traffic each time the first flow communication traffic is measured, and can increase the quantity of generation of the second flow communication traffic, corresponding to the reduction in the first flow communication traffic.

The present invention may also be a communication method for executing the processed described above.

According to the present invention, it is possible to ensure the communication traffic on the communication route simply by providing the communication node with the technology in the network such as the Internet where the communication control apparatuses on the communication routes employed for forwarding data are not all uniformly managed.

### BRIEF DESCRIPTION OF THE DRAWINGS

FIG. 1 is a diagram showing an architecture of a communication system according to a first embodiment of the present invention;

FIG. 2 is a block diagram showing a system configuration of a stabilizing device according to the first embodiment of the present invention;

FIG. 3 is a diagram showing variations in size of a band of another communication node sharing a network;

FIG. 4 is a diagram showing an architecture of the communication system according to a second embodiment of the present invention;

FIG. 5 is a diagram showing an architecture of the communication system according to a third embodiment of the present invention;

FIG. 6 is a flowchart showing congestion control by a communication target device;

FIG. 7 is a flowchart showing congestion control by the communication target device;

FIG. 8 is a flowchart showing congestion control by the communication target device.

### DETAILED DESCRIPTION OF THE PREFERRED EMBODIMENT

Embodiments of the present invention will hereinafter be described with reference to the drawings. Configurations of the following embodiments are exemplifications, and the present invention is not limited to the configurations of the embodiments.

### First Embodiment

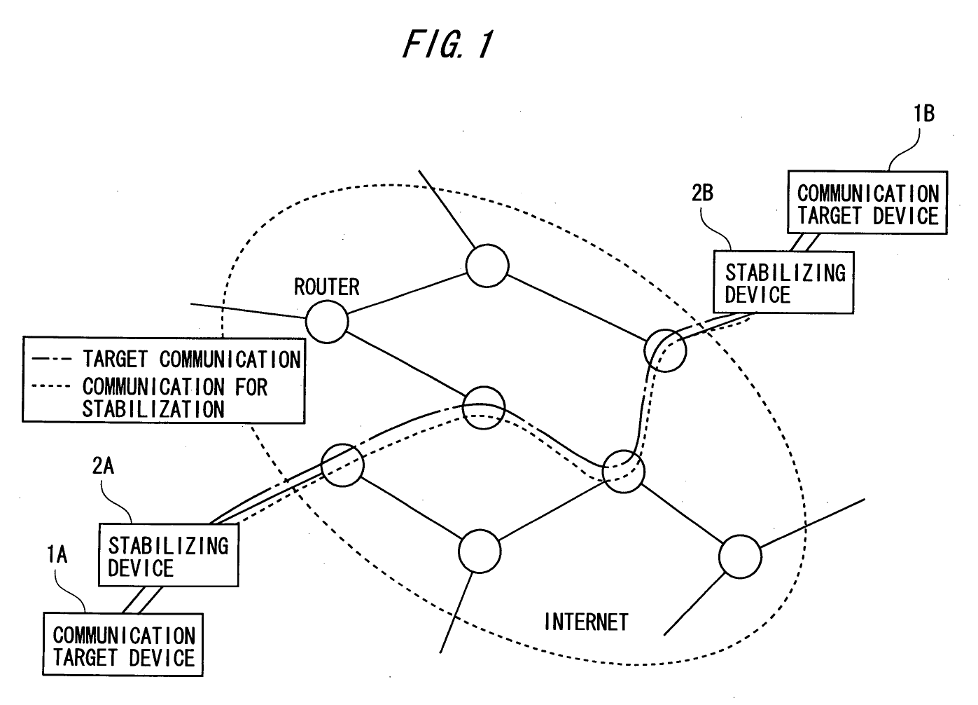

A communication device according to a first embodiment of the present invention will be explained with reference to the drawings in FIGS. 1 through 3.

FIG. 1 is a view of an architecture of a communication system according to the first embodiment. This communication system includes communication target devices 1A and 1B communicating with each other, and stabilizing devices 2A and 2B establishing communicative linkages to the communication target devices 1A and 1B. As shown in FIG. 1, the stabilizing device 2A is provided between the communication target device 1A and the Internet. Further, the stabilizing device 2B is provided between the communication target device 1B and the Internet. The stabilizing device 2A (2B) corresponds to a [communication device] according to the present invention. The communication target device 1A (1B) is a communication terminal such as a personal computer employed by a user. Accordingly, the communication target device 1A (1B) and the stabilizing device 2A (2B) correspond to [communication nodes] according to the present invention. Then, a packet sent by the communication target device 1A (1B) is forwarded to the Internet via the stabilizing device 1A (2B) connected to the communication target 1A (1B). Further, the stabilizing device 2B (2A) receives via the Internet the packet forwarded by the stabilizing device 2A (2B) to the Internet. Then, the stabilizing device 2B (2A) sends the packet to the communication target device 1B (1A).

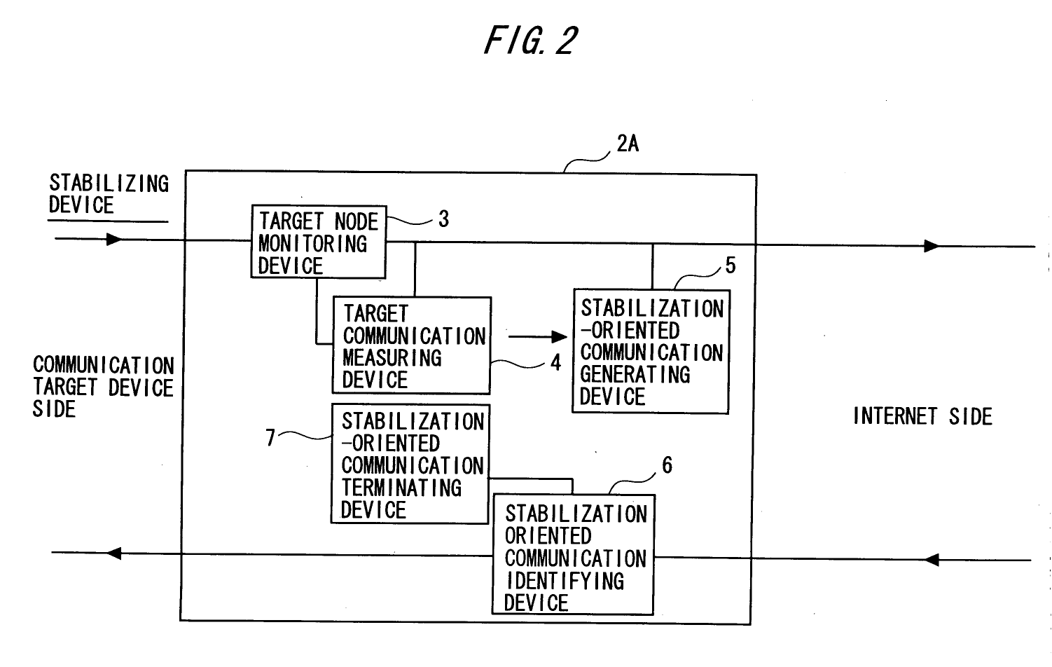

FIG. 2 is a block diagram illustrating a system configuration of the stabilizing device 2A according to the first embodiment of the present invention. As illustrated in FIG. 2, the stabilizing device 2A includes, as components on the side of receiving the packet from the communication target device 1A and forwarding the packet, a target node monitoring device 3, a target communication measuring device 4 and a stabilization-oriented (for-stabilization) communication generating device 5. Further, the stabilizing device 2A includes, as components of the stabilizing device 2A on the side of receiving the packet from the partner stabilizing device 2B, a stabilization-oriented communication identifying device 6 and a stabilization-oriented communication terminating device 7.

Given first are explanations of the components on the side where the stabilizing device 2A receives the packet from the communication target device 1A, i.e., the target node monitoring device 3, the target communication measuring device 4 and the stabilization-oriented communication generating device 5.

The packets handled in the first embodiment are classified mainly into a communication packet received by the stabilizing device 2A from the communication target device 1A and a communication route ensuring packet generated by the stabilization-oriented communication generating device 5. In order to distinguish between these packets, the packet (corresponding to [communication traffic of a first flow] according to the present invention) received by the stabilizing device 2A from the communication target device 1A is referred to as the communication packet, while the packet (corresponding to [communication traffic of a second flow] according to the present invention) generated by the stabilization-oriented communication generating device 5 is referred to as the communication route ensuring packet, respectively. Other than these two types of packets, there may also be a packet, given from the communication target device 1A, for controlling the stabilizing device 2A.

The target node monitoring device 3 receives a designation of using the stabilizing device 2A from the communication target device 1A. This designation contains an IP (Internet Protocol) address of the communication target device 1B as a partner device. The target node monitoring device 3 stores a memory with the received IP address. Further, this designation may also contain a designation of a band ensured on the communication route by the stabilizing device 2A. When the stabilizing device 2A and the communication target device 1A are directly connected to each other via an input/output interface, these designations may be made by a direct input from the communication device 1A to the stabilizing device 2A via the I/O interface. Further, these designations may also be contained in the packet sent by the communication target device 1A. The target node monitoring device 3, upon receiving the designation of using the stabilizing device 2A, notifies the target communication measuring device 4 and the stabilization-oriented communication generating device 5 of the IP address of the communication target device 1B.

Moreover, the target node monitoring device 3, when receiving the packet from the communication target device 1A, reads (corresponding to [reading unit] according to the present invention) the IP address of the partner communication device, which is described in a header of this packet. Then, the target node monitoring device 3 collates the readout IP address in the packet with a registered IP address, and judges whether the readout packet communication is a communication utilizing the stabilizing device 2A or not (corresponding to [judging unit] according to the present invention). Then, the target node monitoring device 3, when judging that the communication of the received packet is the communication using the stabilizing device 2A, sends the packet to the target communication measuring device 4. Further, the target node monitoring device 3, when judging that the communication of the received packet is not the communication using the stabilizing device 2A, forwards the packet toward the Internet.

The target communication measuring device 4 receives the IP address of the communication target device 1B from the target node monitoring device 3. The target communication measuring device 4 stores the received IP address on the memory.

The target communication measuring device 4, when the communication target device 1A performs the communication employing the stabilizing device 2A, receives the packet used for this communication. Then, the target communication measuring device 4 measures a band of the packet received per unit time according to every destination IP address of the received packet (the target communication measuring device 4 corresponds to [measuring unit] according to the present invention). Moreover, the target communication measuring device 4 forwards the received packet to the Internet.

The target communication measuring device 4 measures the band of the packet received per unit time and calculates, based on a size of the measured band of the communication packet, a size of the band of the packet generated by the stabilization-oriented communication generating device 5 (the target communication measuring device 4 corresponds to [calculating unit] according to the present invention). For instance, the target communication measuring device 4 calculates a total band size of the band of the communication packet and the band of the communication route ensuring packet by use of a built-in memory and a built-in central processing unit. Then, the target communication measuring device 4 calculates the size of the band of the communication route ensuring packet to be generated, corresponding to the size of the band of the communication packet so as to keep the size of the band ensured. For example, the target communication measuring device 4, if the band of the communication packet becomes larger than when measured last time, calculates a quantity of generation of the packet so as to reduce, to this degree, the band of the packet to be generated. Further, the target communication measuring device 4, whereas if the band of the communication packet becomes smaller than when measured last time, calculates the quantity of generation of the packet so as to increase, to this degree, the band of the packet to be generated. The target communication measuring device 4 designates a result of the calculation in the stabilization-oriented communication generating device 5.

Given is a specific example of calculating the quantity of generation of the communication route ensuring packet. For instance, let a(t) be a size of the band of the communication packet that is measured t-th time, and let a(t−1) be a size of the band of the communication packet that is measured (t−1)th time. Then, let b(t−1) be a size of the communication route ensuring packet generated (t−1)th time. On this occasion, if the communication route ensuring packet having a size of (t−1)−(a(t)−a(t−1)) is generated t-th time, a total sum of the size of the band of the generated packet and the size of the band of the communication packet becomes a(t−1)+b(t−1)=a(t)+b(t), wherein the total sum of the size of the band of the generated packet and the size of the band of the communication packet does not depend on a point of the measuring time, and the total band of the band of the generated packet and the size of the band of the communication packet is kept constant. Accordingly, the target communication measuring device 4 may, after the measurement of the t-th time, instruct the stabilization-oriented communication generating device 5 to generate the packet of the band having a size given by b(t−1)−(a(t)−a(t−1)). The target communication measuring device 4, which calculates (a(t)−a(t−1)), corresponds to [differential unit] according to the present invention. The target communication measuring device 4, which calculates b(t−1)−(a(t)−a(t−1)), corresponds to [second calculating unit] according to the present invention. The target communication measuring device 4, which designates a result of the calculation such as b(t−1)−(a(t)−a(t−1)) in the stabilization-oriented communication generating device 5, corresponds to [controlling unit controlling to generation] according to the present invention.

The stabilization-oriented communication generating device 5 receives the IP address of the communication target device 1B from the target node monitoring device 3. The stabilization-oriented communication generating device 5 stores the received IP address on the memory. Further, the stabilization-oriented communication generating device 5, when receiving the IP address of the communication target device 1B, sends a notification that the stabilizing device 2A is used to the stabilizing device 2B (or the communication target device 1B). Moreover, the communication target device 1A may send the notification that the stabilizing device 2A is used to the stabilizing device 2B (or the communication device 1B).

The stabilization-oriented communication generating device 5 generates a packet for ensuring the band of the communication route extending from the stabilizing device 2A to the stabilizing device 2B. Further, the stabilization-oriented communication generating device 5, when the stabilizing device 2A receives the communication packet, receives the designation about the quantity of generation of the communication route ensuring packet from the target communication measuring device 4 in order to adjust the size of the band of the communication packet and the size of the band of the communication route ensuring packet. The stabilization-oriented communication generating device 5 (corresponding to [generating unit] according to the present invention) generates the communication route ensuring packet based on the designation given from the target communication measuring device 4. The stabilization-oriented communication generating device 5 may, when generating the packet, generate the packet having an arbitrary size. The stabilizing device 2A, when not receiving the designation about the quantity of generation of the communication route ensuring packet from the target communication device 4, generates the packet of the band designated last time in order to ensure the communication route. Then, the stabilization-oriented communication generating device 5 sends the generated packet to the partner stabilizing device 2B. The band ensured by the stabilization-oriented communication generating device 5 can be ensured by using a generally employed protocol such as TCP (Transmission control Protocol).

The system configuration of the stabilizing device 2A on the side of receiving the packet from the communication target device 1A and sending the packet, has been discussed so far. Next, a stabilization-oriented communication identifying device 6 and a stabilization-oriented communication terminating device 7 will be explained as a system configuration of the stabilizing device 2A on the side where the stabilizing device 2A receives the packet from the partner stabilizing device 2B.

The stabilization-oriented communication identifying device 6 receives, from the communication target device 1B (or the stabilizing device 2B), a notification that the target device 1B employs the stabilizing device 2B. Then, the stabilization-oriented communication identifying device 6, upon receiving this notification, stores the IP address, that is contained in the packet, of the communication target device 1B on the memory provided in the stabilization-oriented communication identifying device 6.

The stabilization-oriented communication identifying device 6 receives the packet from the stabilizing device 2B. The stabilization-oriented communication identifying device 6 judges whether the received packet is the communication route ensuring packet generated by the stabilizing device 2B or the communication packet sent by the communication target device 1B. Then, the stabilization-oriented communication identifying device 6, when judging from a result of identifying the received packet that the received packet is the communication route ensuring packet, sends the received packet to the stabilization-oriented communication terminating device 7. Further, the stabilization-oriented communication identifying device 6, when judging from the result of identifying the received packet that the received packet is the communication packet sent by the communication target device 1B, sends the received packet to the communication target device 1A.

The stabilization-oriented communication terminating device 7 receives the communication route ensuring packet sent by the stabilization-oriented communication identifying device 6. Then, the stabilization-oriented communication terminating device 7 discards the received packet.

Thus, the stabilizing device 2A within the communication node can converge, at within a certain range, the total band of the band of the communication packet received from the communication target device 1A and the band of the communication route ensuring packet generated based on the band of the communication packet. Accordingly, the band ensured by the communication route ensuring packet can be used as the band of the communication packet when the band of the communication packet increases in a way that ensures the communication route with the band of the communication route ensuring packet.

Further, as shown in FIG. 1, the communication target device 1A (1B) can employ the stabilizing device 2A (2B) simply by providing the stabilizing device 2A between the communication target device 1A and the Internet and the stabilizing device 2B between the communication target device 1B and the Internet. Hence, the communication target device 1A (1B) can employ the stabilizing device 2A (2B) even if the communication control device provided on midways of the communication route between the stabilizing device 2A and the stabilizing device 2B does not include the stabilizing device.

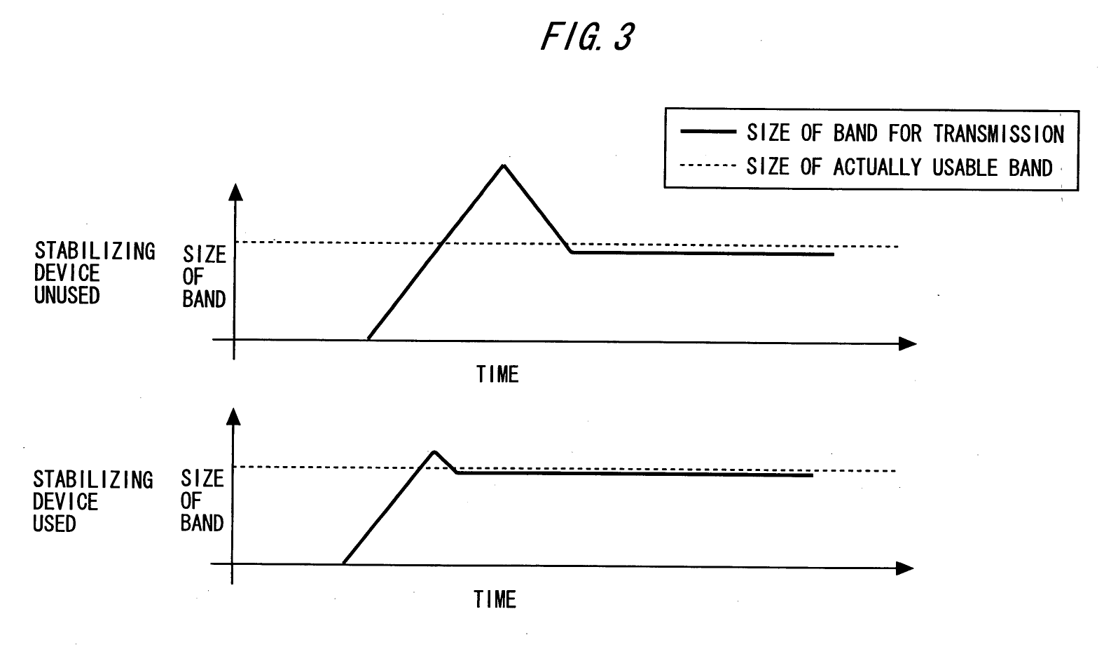

FIG. 3 is a diagram showing variations in the size of the band of another communication node that shares the network. An assumption for an explanation in FIG. 3 is that the communication node used by a certain user is defined as a communication node A, while the communication node employed by another user is defined as a communication node B. Given then is a description of how it is influenced by the communication node A sharing the network when the communication node B starts performing the communication with respect to two ways such as a case where the communication node A does not employ the stabilizing device and a case where the communication node A employs the stabilizing device.

If the communication node A does not include the stabilizing device, the communication node B increases the band of the packet to be sent larger than a usable band when the communication node A performs the communication. Thereafter, when the communication node A starts the communication, the band of the communication node B is restrained for the band of the packet to be sent by the communication node A. With this scheme, the size of the band of the communication node B is restrained down to a size of the usable band when the communication node A performs the communication. A jitter occurs due to such an abrupt change in the band used by one communication node B.

On the other hand, when the communication node A employs the stabilizing device, the stabilizing device for the communication node A previously ensures the band having a predetermined size on the communication route in order to ensure the communication route. Accordingly, the communication node B does not increase the band of the packet to be sent larger than the size of the usable band when the communication node A performs the communication. Therefore, the stabilizing device provided in the communication node A can restrain the aforementioned abrupt change in the band, i.e., the jitter.

### Second Embodiment

A second embodiment is an example in which the present invention is applied to the communications in a network system where a plurality of networks are connected. Explained in this case is an example, wherein a plurality of communication target devices share one stabilizing device in a single network (or one network segment). The Internet (an IP network) is herein considered by way of an example of the network system. Further, a sub-network is considered by way of an example of the network to which the communication target devices belong.

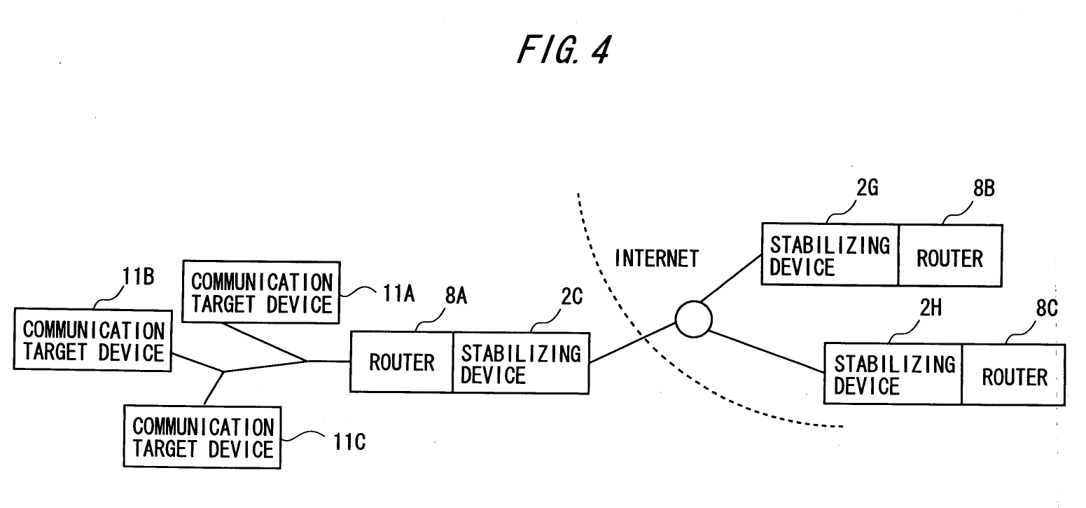

FIG. 4 is a diagram of a structure of the communication system according to the second embodiment. A stabilizing device 2C is provided in a router 8A between communication target devices 11A-11C and the Internet. Then, in such a case that the communication target devices 11A-11C forward the packets to the Internet, the stabilizing device 2C is configured so that these packets are inevitably to be sent through the router 8A and the stabilizing device 2C. Furthermore, in such a case that the communication target devices 11A-11C receive the packets from the Internet, the stabilizing device 2C is configured so that these packets are inevitably to be sent through the stabilizing device 2C and the router 8A. The communication target devices 11A-11C configure a sub-network as a LAN (Local Area Network).

The stabilizing device 2C is provided in the router 8A between the communication target devices 11A-11C and the Internet. The communication target devices 11A-11C forward the packets to the communication target devices belonging to another network via the router 8A. This is exemplified such that any one of the communication target devices 11A-11C forwards the packet to the communication target device connected to a router 8B. When any one of the communication target devices 11A-11C forward the packets to the communication target devices belonging to another network, the packets forwarded by any one of the communication target devices 11A-11C pass through the router 8A connected to the communication target devices 11A-11C. Then, the packets passing through the router 8A are received by the stabilizing device 2C connected to the router 8A. The stabilizing device 2C reads destination IP address from the headers of the packets forwarded by any one of the communication target devices 11A-11C. Then, the stabilizing device 2C measures the band of the packet according to every readout IP address. Then, the stabilizing device 2C calculates a quantity of generation of the communication route ensuring packet according to every readout IP address. Subsequently, the stabilizing device 2C generates, based on a result of the calculation, the communication route ensuring packet. Thereafter, the stabilizing device 2C forwards the generated packet to the IP address read from the received communication packet, i.e., a destination address of the communication packet. Further, the stabilizing device 2C also forwards the received communication packet. Then, the communication packet and the communication route ensuring packet, which have been forwarded across the Internet, are received by a stabilizing device 2G provided in the route 8B to which the partner communication target device is connected. Then, the stabilizing device 2G selects the communication route ensuring packet from among the received packets and discards the selected packet. On the other hand, the stabilizing device 2G forwards the communication packet to the router 8B. Then, the communication packet forwarded by the stabilizing device 2G is received by the router 8B. Subsequently, the router 8B reads a MAC (Media Access Control) address from the header of the received packet. Then, the router 8B judges the partner communication target device from the readout MAC address. Subsequently, the router 8B forwards, based on a result of the judgment, the received packet to the partner communication target device.

Further, the packet forwarded by the partner communication target device passes through the router 8B connected to the partner communication target device. Then, the packet passing through the router 8B is received by the stabilizing device 2G provided in the router 8B. The stabilizing device 2G, in the same way as the stabilizing device 2C operates, generates and forwards the communication router ensuring packet to the Internet. Further, the stabilizing device 2G, in the same way as the stabilizing device 2C operates, forwards the communication packet. Then, the communication packet and the communication route ensuring packet, which have been forwarded to the Internet, go across the Internet and are received by the stabilizing device 2C provided in the router 8B connected to the communication target devices 11A-11C. Then, the stabilizing device 2C selects the communication ensuring packet from among the received packets and discards the selected packet. Further, the stabilizing device 2C forwards the communication packet to the router 8A. Subsequently, the router 8A reads a MAC address of any one of the communication target devices 11A-11C from the header of the communication packet. Then, the router 8A judges from the MAC address read by the router 8A itself which device among the communication target devices 11A-11C the partner device performs the communication with. Subsequently, the router 8A forwards, based on a result of the judgment, the packet to the judged communication target device.

Accordingly, the router 8A connected to the communication target devices 11A-11C and the router 8B connected to the partner communication target device, are provided with the stabilizing devices 2C and 2G respectively, thereby enabling the stabilizing devices 2C and 2G to generate the communication router ensuring packets between the two routers. Then, when the stabilizing device 2C, provided in the router to which the communication target devices 11A-11C are connected, generates the communication route ensuring packet between the two routers, the communication target devices 11A-11C can use the band ensured by this communication route ensuring packet also as a band of the communication packet of each of the communication target devices 11A-11C. Thus, even when the plurality of networks are connected, the communication target device can employ the stabilizing device by providing the router with the stabilizing device.

Further, as described above, the stabilizing device 2C controls the packet on the IP-address-by-IP-address basis of the partner communication target device, which address is read from the received packet. Namely, the stabilizing device 2C measures the size of the band of the packet on the IP-address-by-IP-address basis, calculates the size of the band of the packet generated on the IP-address-by-IP-address basis, and generates, based on a result of this calculation, the packet. Therefore, even when each of the communication target devices 11A-11C forwards the packets to the communication target devices belonging to the sub-networks different from each other by use of the stabilizing device, the communication target devices 11A-11C can employ the stabilizing device 2C. In this case, the stabilizing devices 2C and 2G provide a function of stabilizing the communication traffic (communication band) between the two networks identified by network addresses. Note that there may be a plurality of partner networks serving as targets for the stabilization.

Further, the stabilizing device 2C may be separated from the router 8A and may also be united with the router 8A.

### Third Embodiment

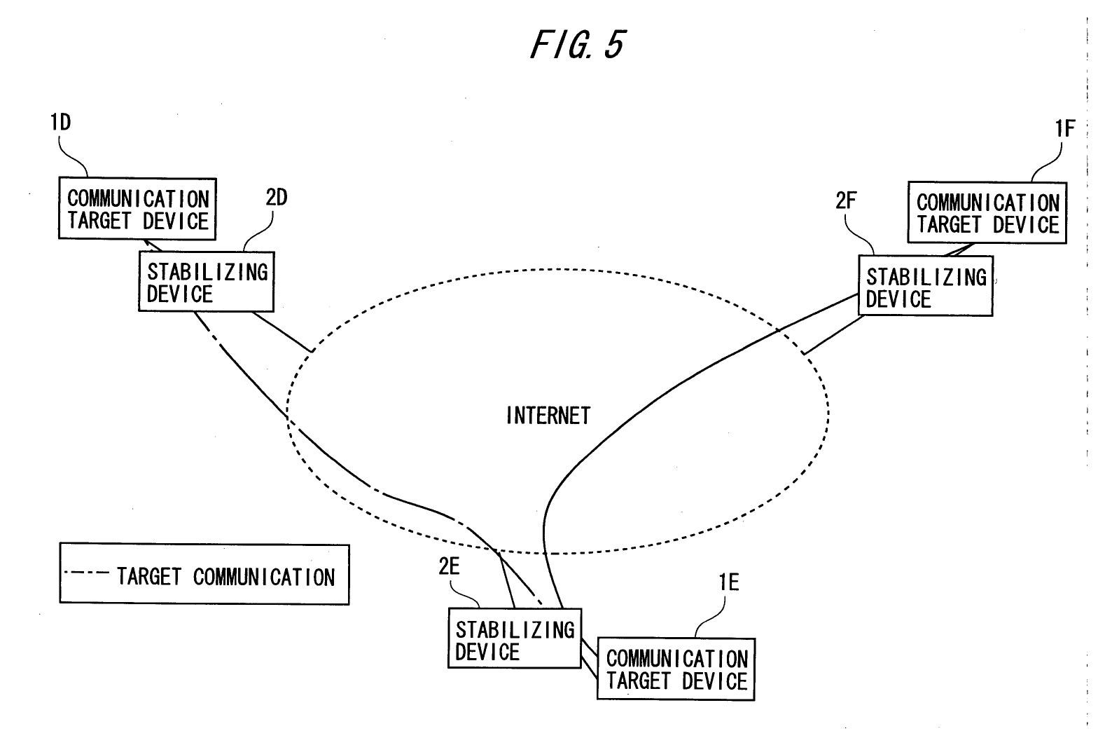

FIG. 5 is a diagram of a structure of the communication system according to a third embodiment. FIG. 5 illustrates how a communication target device 1E communicates with a target communication device 1D via a stabilizing device 2E and a stabilizing device 2D, and communicates with the target communication device 1F via the stabilizing device 2E and a stabilizing device 2F.

In the case of the structure shown in FIG. 5, the stabilizing device 2E measures a size of the band of the packet according to every destination IP address of the packet received from the communication target device 1E. Then, the stabilizing device 2E calculates a quantity of generation of the communication route ensuring packet according to the every destination IP address of the packet received from the communication target device 1E. Further, the stabilizing device 2E generates, based on the calculated quantity of generation of the packet, the communication route ensuring packet according to every destination IP address of the packet received from the communication target device 1E. Moreover, the stabilizing device 2E forwards the generated packet to the destination of the packet received from the communication target device 1E.

Thus, the communication target device 1E can employ the stabilizing device 2E also for the plurality of communication nodes.

<Flowchart of Congestion Control by Communication Target Device>

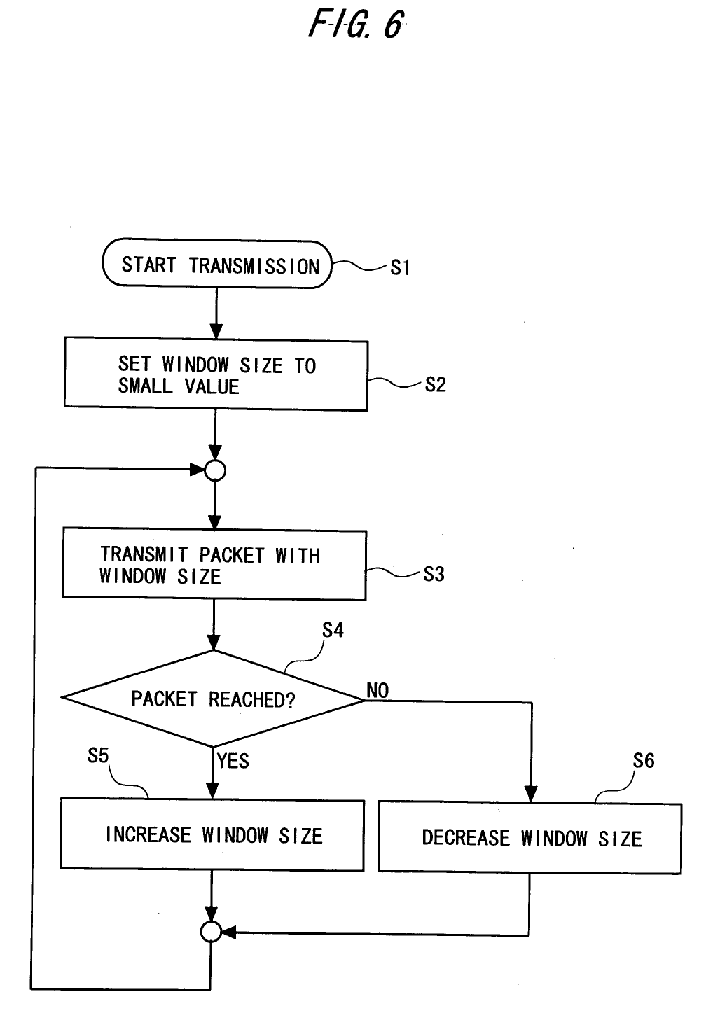

FIG. 6 is a flowchart of congestion control by the communication target device 1A. The communication target device 1A is assumed to be a communication terminal such as a personal computer etc. used by the user, and the personal computer etc. controls a packet congestion generally based on the TCP. Accordingly, the communication target device 1A controls a congestion of the packets also in the communication target device 1A. Moreover, the communication target device 1A controls the congestion independently of whether the stabilizing device 2A is used or not. Further, the stabilizing device 2A measures the band of the packet forwarded by the communication target device 1A and generates, based on a result of the measurement, the packet. Therefore, the discussion on the congestion control of the communication target device 1A and a description of a characteristic of the band of the packet forwarded by the communication target device 1A, involve explaining a flowchart of the congestion control by the communication target device 1A. The congestion control by the communication target device 1A may not, however, be limited to being based on the TCP.

To start with, the communication target device 1A sends the communication packet to the partner communication device (S1). The communication target device 1A controls the packet on the basis of the TCP. In the TCP, a buffer called a window for storing a plurality of packets is provided, and the packets are controlled on a buffer-by-buffer basis. A window size is related to a size of the band for sending the packet. The communication target device 1A at first sets the window size to a small value (S2). Then, the packets stored in the small-sized window are sent (S3).

The communication target device 1B, upon receiving the packet, sends ACK (Acknowledgement) showing that the packet is received, i.e., a notification of confirmation to the communication target device 1A as a source device. The communication target device 1A stores the packet sent from the window till ACK is reached. Then, when ACK is reached, the communication target device 1A discards the packet of which the reception by the communication target device 1B has been confirmed by ACK. Thus, the communication target devices 1A and 1B can perform the reliability-ensured communications by use of the TCP.

The communication target device 1A judges from the ACK whether the packet reaches the communication target device 1B or not (S4). When the ACK reaches the communication target device 1A, the communication target device 1A is enabled to perform higher-speed communications by increasing the window size. Hence, in step S4, when the ACK reaches the communication target device 1A, the communication target device 1A increases the window size. Further, if the ACK does not reach the communication target device 1A, there is a possibility that the forwarded packet does not reach the partner communication target device 1B, and hence the communication target device 1A is required to decrease the window size and to reduce the size of the band for sending the packet. Accordingly, in step S4, if the ACK does not reach the communication target device 1A, the communication target device 1A decreases the window size.

Thus, the communication target device 1A controls the congestion of the packets to be sent.

<Flowchart of Congestion Control by Stabilizing Device>

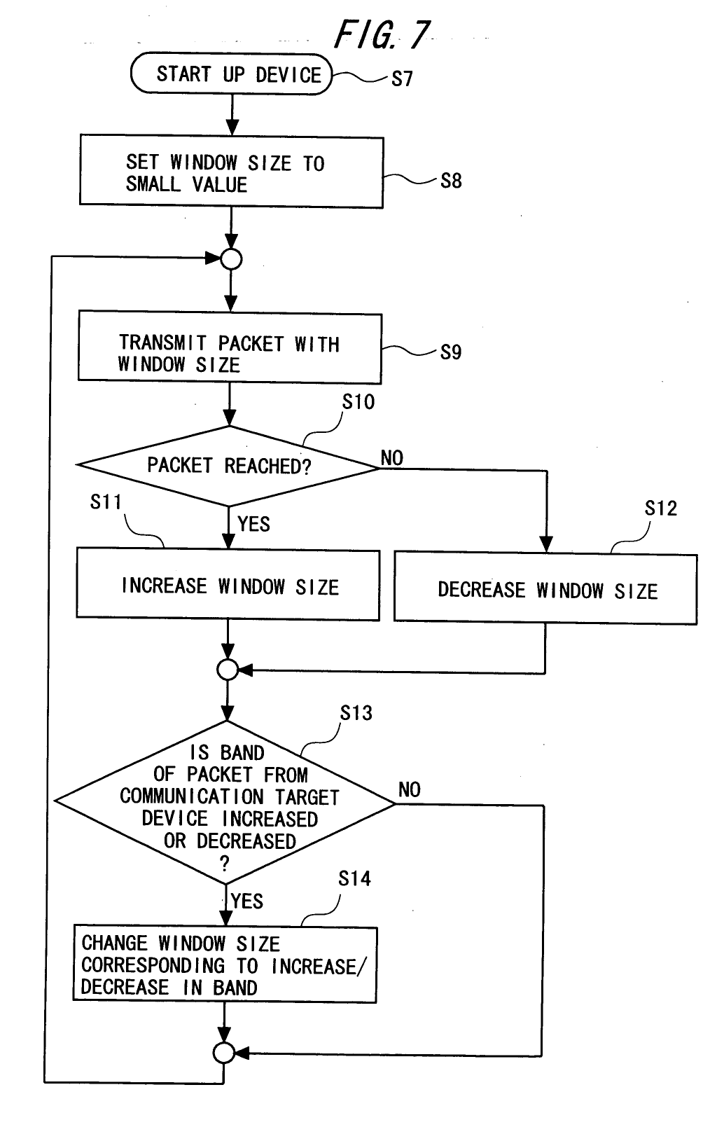

FIG. 7 is a flowchart of the congestion control by the stabilizing device 2A. In FIG. 6, the flowchart of the congestion control by the communication target device 1A has been explained. In FIG. 7, the stabilizing device 2A controls the congestion on the basis of a result of measuring the band of the packet forwarded by the communication target device 1A.

The stabilizing device 2A, as by the communication target device 1A explained referring to FIG. 6, controls the packet on the basis of the TCP. The stabilizing device 2A may not, however, control the packet based on the TCP as by the communication target device 1A explained referring to FIG. 6.

To begin with, the stabilizing device 2A is started up (S7). The stabilizing device 2A receives the IP address of the communication target device 1A as a notification for use of the stabilizing device 2A. The stabilizing device 2A, in the same way as the communication target device 1A shown in FIG. 6 operates, for the first time, sets a small-sized window. In the same way as the communication target device 1A shown in FIG. 6 operates, the stabilizing device 2A transmits the packed stored in the window (S9). In the same way as the communication target device 1A shown in FIG. 6 operates, the stabilizing device 2A judges whether the ACK is reached from the communication target device 1B or not (S10). In the same way as the communication target device 1A shown in FIG. 6 operates, when it is judged in step S10 that the ACK given from the communication target device 1B reaches the stabilizing device 2A, the stabilizing device 1A increases the window size (S11). Further, whereas when it is judged in step S10 that the ACK given from the communication target device 1B does not reach the stabilizing device 2A, the stabilizing device 1A decreases the window size (S12).

In this flowchart, the communication route ensuring packet generated by the stabilizing device 2A is controlled by a different window from the window for the communication packet received by the stabilizing device 2A. The stabilizing device 2A may send the received communication packet by use of the same window as the window for the communication route ensuring packet generated.

Thus, the stabilizing device 2A increases the window size so as to gain approximation to the size of the band of the packet that is designated from the communication target device 1A or the preset band size. Then, the stabilizing device 2A, if capable of ensuring the designated band size, keeps the window having this size. Further, the stabilizing device 2A, whereas if incapable of ensuring the designated band size, tries to ensure the band size in a way that increases little by little the window size in order to ensure the designated band size. Furthermore, the stabilizing device 2A, if unable to ensure the designated band size, after trying to increase the window size up to a certain point of time, may decrease the window size down to such a window size that the ACK comes from the communication target device 1B substantially surely. Thus, the stabilizing device 2A ensures the communication route extending to the communication target device 1B through the packet generated by the stabilizing device 2A.

The stabilizing device 2A compares a measured result of the band of the received packet that is measured per unit time at an interval of the unit time. The stabilizing device 2A, as a result of the comparison between the measured packet band and the packet band measured the unit time ago, judges whether the band of the received packet increases or decreases (S13). If it is judged in step S13 that the band of the packet from the communication target device 1A increases, it is required that the quantity of generation of the communication route ensuring packet generated by the stabilizing device 2A be decreased corresponding to this increase quantity. Hence, the stabilizing device 2A decreases the size of the window for the communication route ensuring packet that is provided in the stabilizing device 2A so that the quantity of generation of the communication route ensuring packet is decreased corresponding to the increase in the band of the packet from the communication target device 1A. Further, if it is judged in step S13 that the band of the packet from the communication target device 1A decreases, it is required that the quantity of generation of the communication route ensuring packet generated by the stabilizing device 2A be increased corresponding to this decrease quantity. Therefore, the stabilizing device 2A increases the size of the window for the communication route ensuring packet that is provided in the stabilizing device 2A so that the quantity of generation of the communication route ensuring packet is increased corresponding to the decrease in the band of the packet from the communication target device 1A. Thus, the stabilizing device 2A compares the measured band of the received packet with the band of the received packet that was measured the unit time ago, and decreases or increases the window size corresponding to the increase or decrease of the received packets (S14).

In the way described above, the stabilizing device 2A can control, based on the band of the received communication packet, the band of the communication route ensuring packet to be generated and then forwarded.

<Flowchart of Operation of Stabilizing Device>

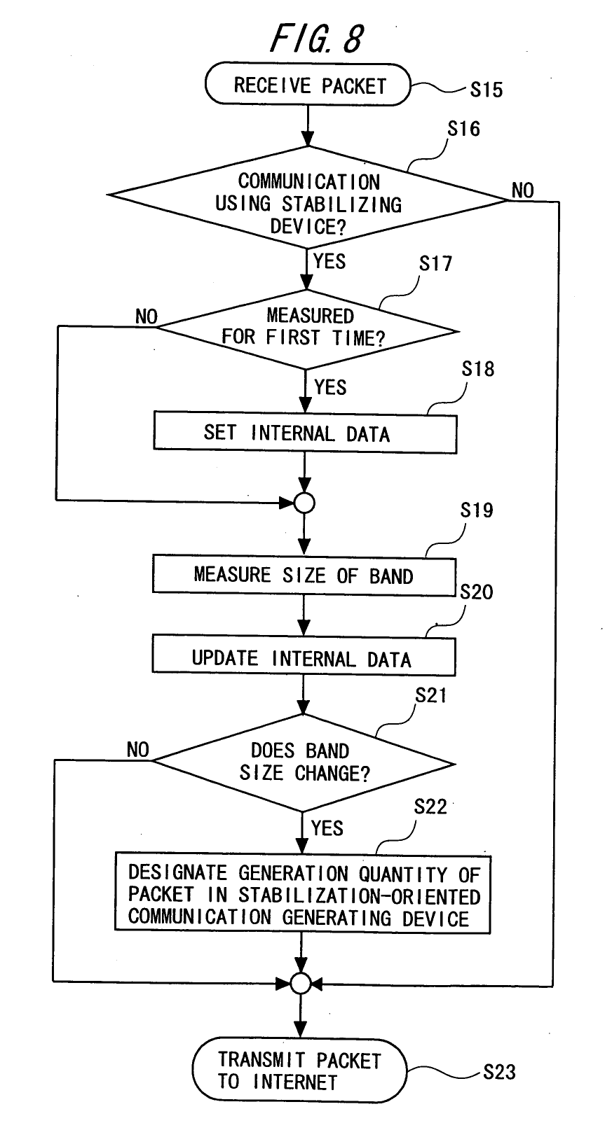

FIG. 8 is a flowchart of an operation of the stabilizing device 2A. This flowchart shows the operation of the stabilizing device 2A especially till the stabilizing device 2A receives the packet from the communication target device 1A and forwards the packet toward the Internet.

To start with, the stabilizing device 2A receives the packet from the communication target device 1A (S15). Next, the stabilizing device 2A judges from the IP address described in the header of the received packet whether the received packet is the communication packet using the stabilizing device 2A or not by comparing with the IP address registered therein (S16).

When judging in step S16 that the received packet is the communication packet using the stabilizing device 2A, the target node monitoring device 3 sends the received packet to the target communication measuring device 4. Further, When judging in step S16 that the received packet is not the communication packet using the stabilizing device 2A, the target node monitoring device 3 forwards the received packet to the Internet (S23).

The target communication measuring device 4, upon receiving the packet, reads the destination IP address of the received packet. Then, the target communication measuring device 4 judges whether or not the received packet is a packet subjected first to the measurement since the stabilizing device 2A received the notification that the stabilizing device is employed (S17). When judging in step S17 that the received packet is the packet subjected first to the measurement, the target communication measuring device 4 sets internal data with respect to the IP address contained in this packet (S18). This setting is such that when receiving the packet, there is set a file etc. for describing the size of the band of the packet with respect to the IP address of the partner communication device to which this packet is forwarded.

Next, the target communication measuring device 4 measures the size of the band of the packet (S19). Then, the target communication measuring device 4 additionally writes the band size measured in step S19 to the internal data. On this occasion, if the measurement with respect to the IP address contained in this packet is not the first time, the new internal data and the old internal data are updated (S20). For instance, in the internal data, the band size measured last time may be set to an old value, and the band size measured this time may also be set to a new value. Further, on this occasion, if the band is not measured, zero may be given as an old value.

Then, the target communication measuring device 4 compares the band size measured afresh with the band size measured last time, and thus judges whether the band changes or not (S21). Moreover, on the occasion of the judgment in step S21, if an increase in absolute value of the change quantity of the band of the communication packet gets equal to or smaller than a certain predetermined value, it may be judged that there is no change in the band size.

When judging in step S21 that there is no change in the band size, the target communication measuring device 4 notifies of the stabilization-oriented communication generating device 5 of nothing, and forwards the measured packet to the Internet (S23).

When judging in step S21 that the band size changes, the target communication measuring device 4 calculates a quantity of generation of the communication route ensuring packet by use of the internal data. Then, the target communication measuring device 4 designates a result of the calculation in the stabilization-oriented communication generating device 5 (S22). Then, the target communication measuring device 4 forwards the measured packet to the Internet (S23). Subsequently, the stabilization-oriented communication generating device 5 generates the packet based on the designation of the generation quantity of the communication route ensuring packet sent from the target communication measuring device 4.

### MODIFIED EXAMPLES

The stabilizing device may be implemented in a hardware or as a software provided in the communication target device. Further, the stabilizing device may also be implemented separately from the communication target device. In this case, the stabilizing device may independently have the destination addresses such as the IP address and the MAC address separately from the communication target device.

Moreover, even when the partner communication target device does not include the stabilizing device, the stabilizing device can be applied in a way of setting in the partner communication node so as to discard the communication route ensuring packet generated by the stabilizing device. For example, if the partner communication node does not include the stabilizing device, the stabilizing device may designate the destination address of the packet to be generated in a port for discarding in the partner communication node.

Further, the stabilizing device can be used for communication networks other than the Internet.

### INCORPORATION BY REFERENCE

The disclosures of Japanese patent application No. JP2005-192475 filed on Jun. 30, 2005 including the specification, drawings and abstract are incorporated herein by reference.

What is claimed is:

1. A communication apparatus comprising:
a measuring unit measuring a communication traffic of a first flow that contributes to a band of communication with a partner communication apparatus;
a calculating unit calculating a communication traffic of a second flow so that a total communication traffic of the communication traffic of the first flow measured by the measuring unit and of the communication traffic of the second flow that can be generated based on a result of the measurement made by the measuring unit, is to be contained within a predetermined range; and
a generating unit generating the communication traffic of the second flow for forwarding the communication traffic of the second flow to the partner communication apparatus on the basis of a result of the calculation made by the calculating unit.

2. A communication apparatus according to claim 1, wherein the measuring unit includes:
a reading unit reading a destination address of the partner communication apparatus from the communication traffic of the first flow that contributes to the band of the communication with the partner communication apparatus;
a judging unit judging whether or not the destination address read by the reading unit is coincident with a predetermined destination address; and
a communication traffic measuring unit measuring a communication traffic of the first flow to the destination address judged to be coincident by the judging unit.

3. A communication apparatus according to claim 1, further comprising:
a differential unit obtaining a size which is calculated by subtracting a size of the communication traffic of the first flow measured by the measuring unit from a size of the communication traffic of the first flow measured last time by the measuring unit;
second calculating unit calculating a communication traffic of a size which is calculated by subtracting a size of the communication traffic of the second flow calculated by the calculating unit after being measured last time by the measuring unit from a difference size of the communication traffic that is obtained by the differential unit; and
a controlling unit controlling to generate the communication traffic of the second flow for forwarding the communication traffic of the second flow to the partner communication apparatus on the basis of a result of the calculation made by the second calculating unit.

4. A communication method comprising:
a measuring step of measuring a communication traffic of a first flow that contributes to a band of communication with a partner communication apparatus;
a calculating step of calculating a communication traffic of a second flow so that a total communication traffic of the communication traffic of the first flow measured in the measuring step and the communication traffic of the second flow that can be generated based on a result of the measurement made in the measuring step, is to be contained within a predetermined range; and
a step of generating the communication traffic of the second flow for forwarding the communication traffic of the second flow to the partner communication apparatus on the basis of a result of the calculation made in the calculating step.

5. A communication method according to claim 4, wherein the measuring step includes executing:
a step of reading a destination address of the partner communication apparatus from the communication traffic of the first flow that contributes to the band of the communication with the partner communication apparatus;
a judging step of judging whether or not the destination address read in the reading step is coincident with a predetermined destination address; and
a communication traffic measuring step of measuring a communication traffic of the first flow to the destination address judged to be coincident in the judging step.

6. A communication method according to claims 4, further comprising:
a differential step of obtaining a size which is calculated by subtracting a size of the communication traffic of the first flow measured in the measuring step from a size of the communication traffic of the first flow measured last time in the measuring step;
a second calculating step of calculating a communication traffic of a size which is calculated by subtracting a size of the communication traffic of the second flow calculated in the calculating step after being measured last time in the measuring step from a difference size of the communication traffic that is obtained in the differential step; and
a step of controlling to generate the communication traffic of the second flow for forwarding the communication traffic of the second flow to the partner communication apparatus on the basis of a result of the calculation made in the second calculating step.
